(19) United States
(12) Patent Application Publication
(10) Pub. No.: US 2016/0300964 A1
(43) Pub. Date: Oct. 13, 2016

(54) SOLAR BATTERY USING SURFACE-PLASMON RESONANCE EFFECT AND METHOD OF MAKING SAME

(71) Applicant: NATIONAL CENTRAL UNIVERSITY, Taoyuan City (TW)

(72) Inventor: Cheng-Lun HSIN, Taoyuan City (TW)

(21) Appl. No.: 15/085,116

(22) Filed: Mar. 30, 2016

(30) Foreign Application Priority Data
Apr. 13, 2015 (TW) 104111795

(51) Int. Cl. H01L 31/0224; H01L 31/02

(52) U.S. Cl. CPC H01L 31/022425; H01L 31/02013

(57) ABSTRACT

A solar battery includes a substrate having a surface, a first electrode and a second electrode arranged on the surface of the substrate with a narrow gap left therebetween, and a structural member arranged on one border edge of the first electrode adjacent to the narrow gap. Thus, when light is irradiated to the structural member, the unreflected light causes creation of surface plasmons on the first electrode and a potential difference relative to the second electrode so that free electrons can flow along the surface of the first electrode and the surface of the second electrode to further generate a current signal.

### BACKGROUND OF THE INVENTION

1. Field of the Invention

The present invention relates to photoelectric conversion technology and more particularly, to a solar battery using surface-plasmon resonance effect.

2. Description of the Related Art

In recent years, as a result of industrialization, the burning of a large number of raw materials induces a greenhouse effect. Under the impact of global warming and severe climate change, countries in the world have come to realize the importance of alternative energy sources. Alternative energy sources such as wind, hydro, geothermal and solar energy are most attractive green energy. Among these green energy, solar energy has a high conversion efficiency and is the most mature technology, and therefore, solar energy is considered as the best alternative energy.

Because silicon is the main material for the semiconductor industry, we have accumulated a considerable experience for silicon processing. Therefore, silicon technology it is quite suitable for the production of solar battery. However, since silicon solar battery has an energy gap about 1.1 electron volts, it can simply absorb the near-infrared light of wavelength about 1000 nm or less, visible and ultraviolet light. Long wavelength infrared light is not fully absorbable by silicon solar battery. Short wavelength blue-violet light has only a small fraction of low energy can be utilized by silicon solar battery, and the other part of short wavelength blue-violet light will be converted into heat energy. Thus, silicon solar battery cannot fully utilize all wavelengths of light, resulting in a difficulty in improving the light-to-electric energy conversion yield.

In order to improve the photoelectric conversion efficiency of solar battery, the current main research direction is to combine materials with different band gap energies for absorbing different wavelengths in sunlight. For example, connecting a nonsilicon solar battery of about 1.7 eV and a silicon battery of about 1.1 eV in series can absorb two different wavelengths of light to increase photoelectric conversion efficiency from about 6%˜8% to about 10%˜12%. There is also a high photoelectric conversion efficiency of the solar battery that has the high energy gap of gallium indium phosphide (GaInP), medium energy gap of gallium indium arsenide (GaInAs) and low energy gap of germanium arranged in a stack. Combining these three different energy gap materials can absorb light in the wavelength range from the ultraviolet to the far-infrared, increasing the overall photoelectric conversion efficiency to about 40%. However, this laminated solar battery is expensive to manufacture, and therefore, it cannot be widely used in our daily lives.

### SUMMARY OF THE INVENTION

The present invention has been accomplished under the circumstances in view. It is the main object of the present invention to provide a solar battery using surface-plasmon resonance effect, which can receive all wavelengths of sunlight for photoelectric conversion and, which is inexpensive to manufacture.

To achieve this and other objects of the present invention, a solar battery comprises a substrate, a first electrode, a second electrode, and a structural member. The first electrode and the second electrode are arranged on the surface of the substrate with a narrow gap left therebetween. The structural member is arranged on one border edge of the first electrode adjacent to the narrow gap for causing creation of a surface-plasmon resonance effect on a surface of said first electrode. Thus, when light is irradiated to the structural member, unreflected light causes creation of surface plasmons on the first electrode and a potential difference relative to the second electrode so that free electrons can flow with unreflected light along the surface of the first electrode and the surface of the second electrode to further generate a current signal, achieving photoelectric conversion.

Preferably, the invention further comprises a third electrode arranged on the surface of the substrate within the narrow gap to enhance conduction between the first electrode and the second electrode.

Preferably, a lead wire is connected between the first electrode and the second electrode and extended over the narrow gap to enhance conduction between the first electrode and the second electrode.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a schematic top view of a solar battery in accordance with a first embodiment of the present invention.

FIG. 2 is a schematic side view of the solar battery in accordance with the first embodiment of the present invention.

FIG. 3 is an enlarged view of a part of FIG. 2.

FIG. 4 is a manufacturing flow illustrating the fabrication of the solar battery in accordance with the first embodiment of the present invention.

FIG. 5 is a schematic top view of a solar battery in accordance with a second embodiment of the present invention.

FIG. 6 is a schematic side view of the solar battery in accordance with the second embodiment of the present invention.

FIG. 7 is a manufacturing flow illustrating the fabrication of the solar battery in accordance with the second embodiment of the present invention.

FIG. 8 is a schematic top view of a solar battery in accordance with a third embodiment of the present invention.

FIG. 9 is a schematic side view of the solar battery in accordance with the third embodiment of the present invention.

FIG. 10 is a manufacturing flow illustrating the fabrication of the solar battery in accordance with the third embodiment of the present invention.

FIG. 11 is a coordinate diagram of the third embodiment of the present invention, illustrating the relationship between voltage and current.

FIG. 12 is a coordinate diagram of the present invention, illustrating the relationship between light and electric power at different wavelengths.

FIG. 13 is another coordinate diagram of the present invention, illustrating the characteristics of performance of two sets of solar batteries connected in series and in parallel.

### DETAILED DESCRIPTION OF THE INVENTION

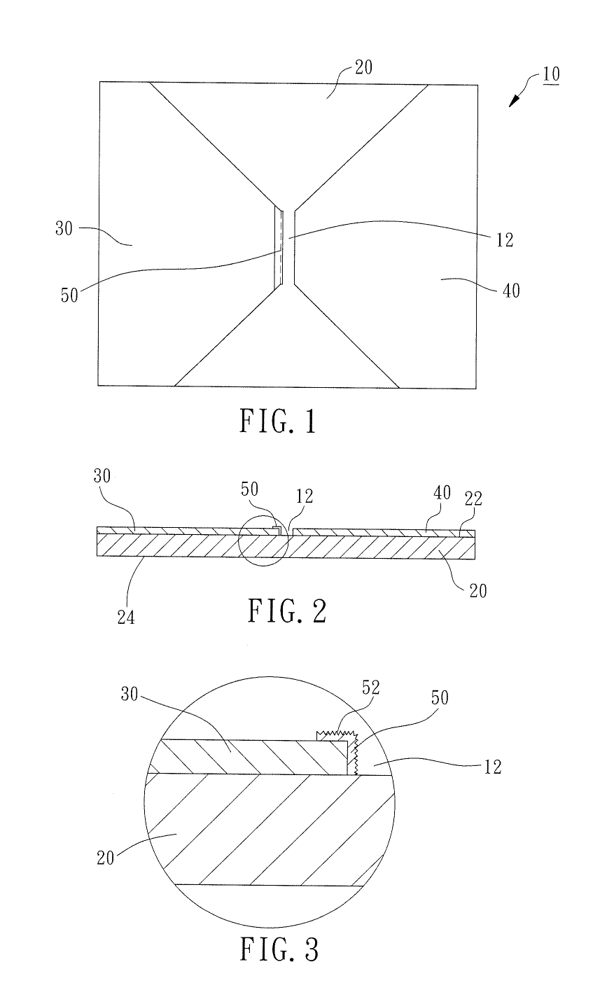

Referring to FIGS. 1 and 2, a solar battery 10 in accordance with a first embodiment of the present invention is shown. The solar battery 10 comprises a substrate 20, a first electrode 30, a second electrode 40, and a structural member 50.

The substrate 20 is made from an insulation material, defining a top surface 22 and an opposing bottom surface 24.

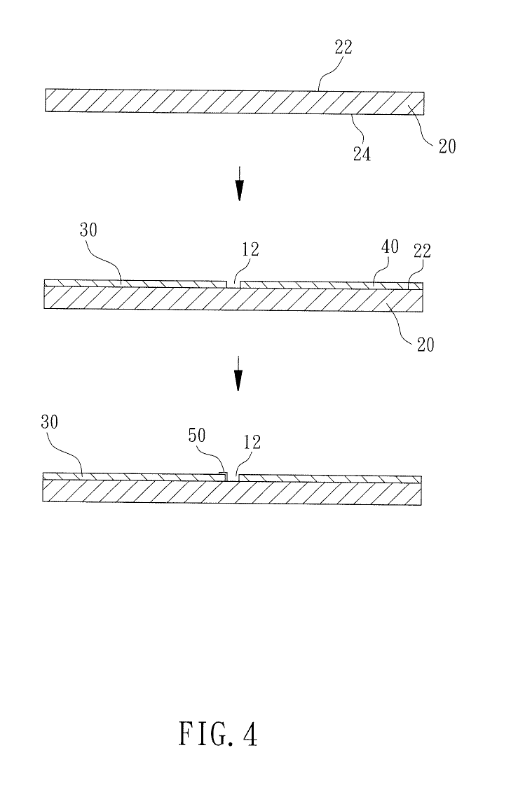

The first electrode 30 is made from a metal material, preferably the high stability gold. During fabrication, as shown in FIG. 4, the first electrode 30 is formed on the top surface 22 of the substrate 20 by sputter deposition.

The second electrode 40 is made from a metal material, preferably the high stability gold. During fabrication, as shown in FIG. 4, the second electrode 40 is formed on the top surface 22 of the substrate 20 by sputter deposition and spaced from the first electrode 30 at a predetermined distance, so that a narrow gap 12 is defined on the top surface 22 of the substrate 20 between the first electrode 30 and the second electrode 40.

The structural member 50 is made from a metal material, preferably the high stability gold. During fabrication, as shown in FIG. 4, the structural member 50 is formed on one border edge of the first electrode 30 adjacent to the narrow gap 12 by sputter deposition, and raised from the surface of the first electrode 30. Further, the structural member 50 has a coarsened surface 52, as shown in FIG. 3. The coarsened surface 52 can be configured to exhibit, but not limited to, serrated, bump-like or other geometric shapes that can be arranged either regularly or irregularly.

Thus, when light is irradiated to the surface of the first electrode 30 and the surface of the second electrode 40, the design of the coarsened surface 52 of the structural member 50 enables unreflected light to have sufficient energy for causing creation of surface plasmons on the first electrode 30 and a potential difference relative to the second electrode 40 so that free electrons can flow along the surface of the first electrode 30 and the surface of the second electrode 40 to further generate a current signal.

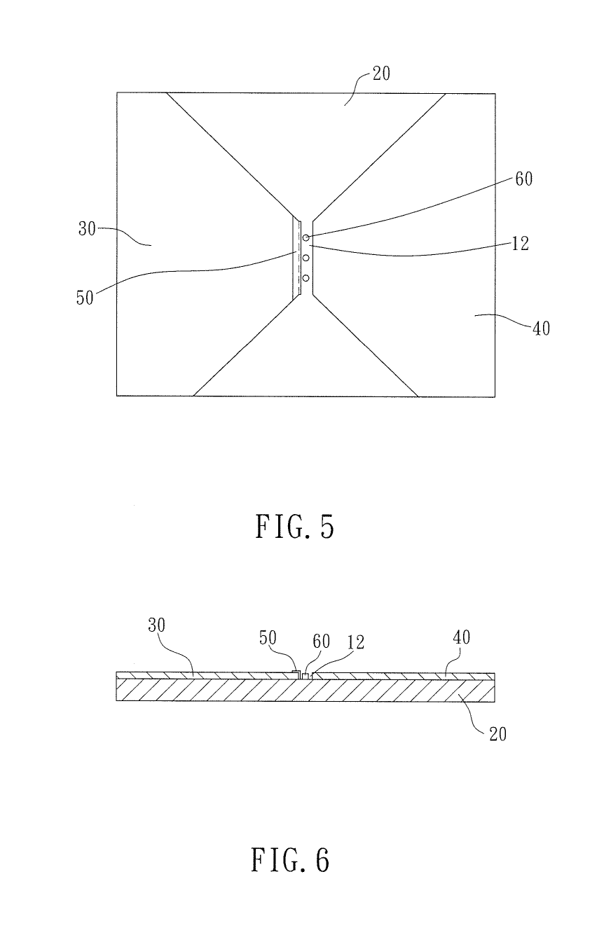

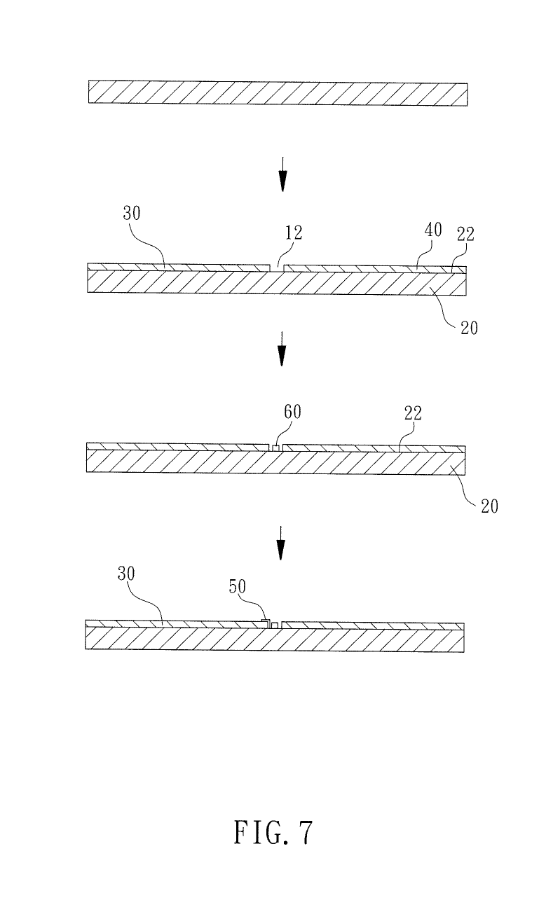

In order to ensure stable output of current signal, the invention provides a second embodiment, as shown in FIGS. 4 and 5, which further comprises at least one, for example, multiple third electrodes 60. The third electrodes 60 are preferably made from high stability gold. During fabrication, as shown in FIG. 7, after formation of the first electrode 30 and the second electrode 40 on the top surface 22 of the substrate 20, third electrodes 60 are formed on the top surface 22 of the substrate 20 within the narrow gap 12 by sputter deposition, and then the designed structural member 50 is formed on the first electrode 30 adjacent to the narrow gap 12. Thus, the arrangement of the third electrodes 60 greatly enhances the flowing of free electrons along the surface of the first electrode 30 and the surface of the second electrode 40.

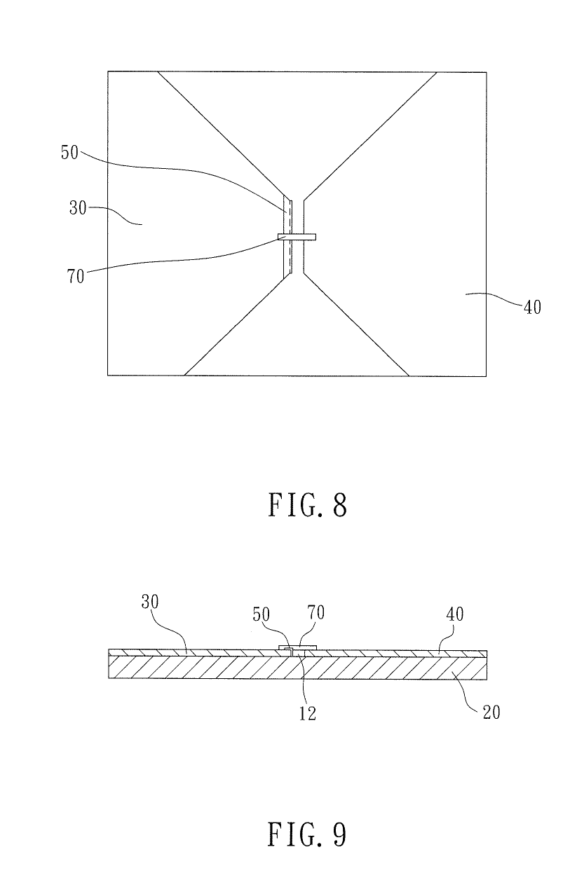

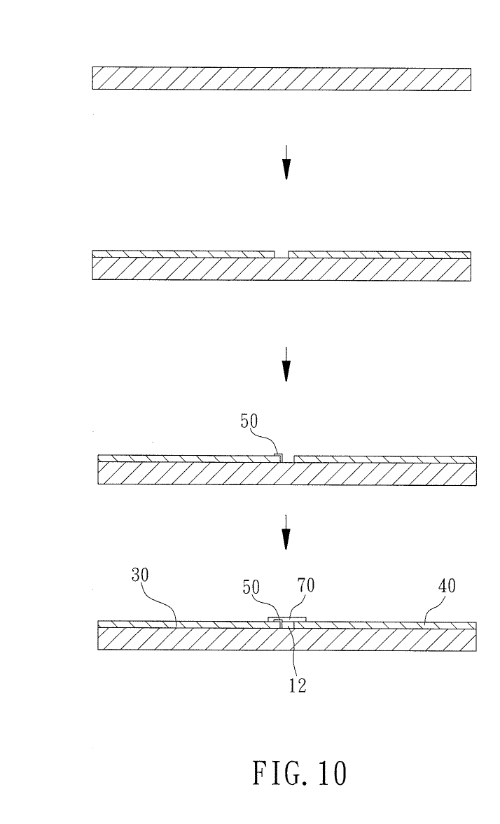

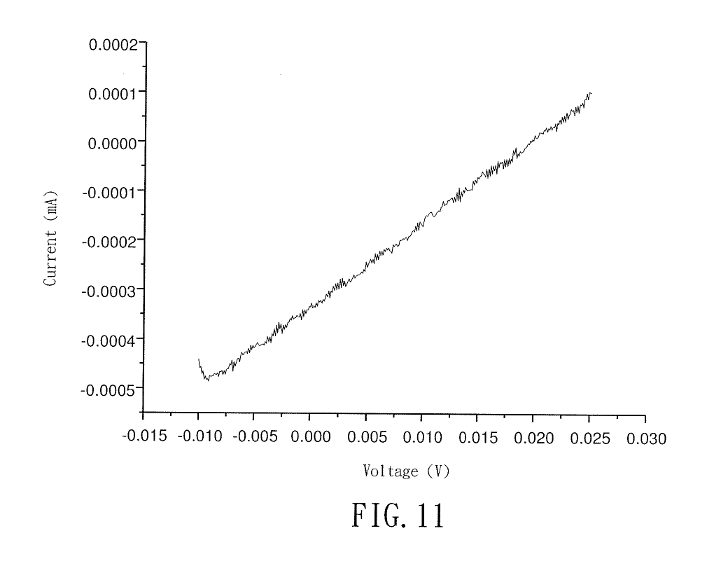

In addition to the arrangement of the third electrodes 60, a third embodiment of the present invention provides a measure to further enhance the flowing of free electrons. As illustrated in FIGS. 8-10, after formation of the structural member 50, a lead wire 70 is extended over the narrow gap 12 and connected between the first electrode 30 and the second electrode 40 so that free electrodes can freely flow between the surface of the first electrode 30 and the surface of the second electrode 40 via the lead wire 70. From the illustration in FIG. 11, different currents can be generated between the first electrode 30 and the second electrode 40 at different voltages.

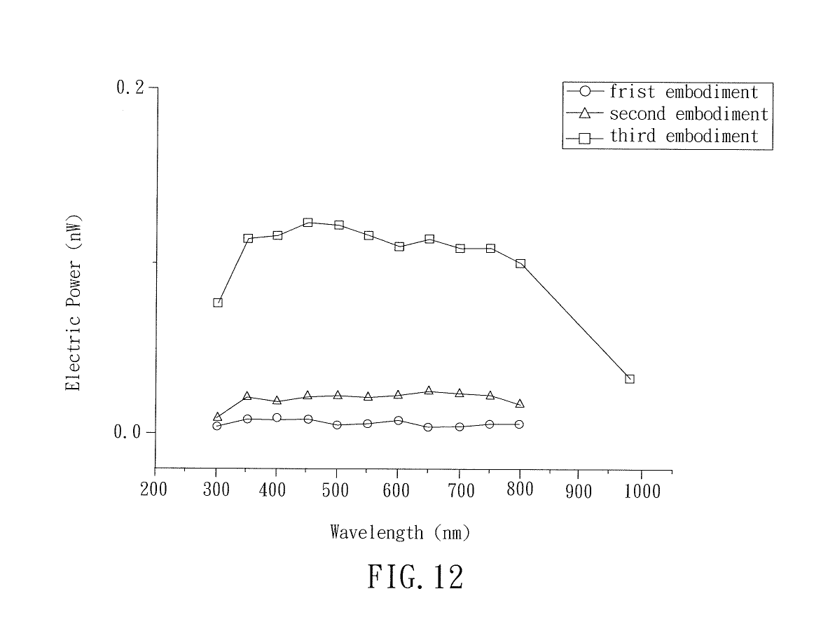

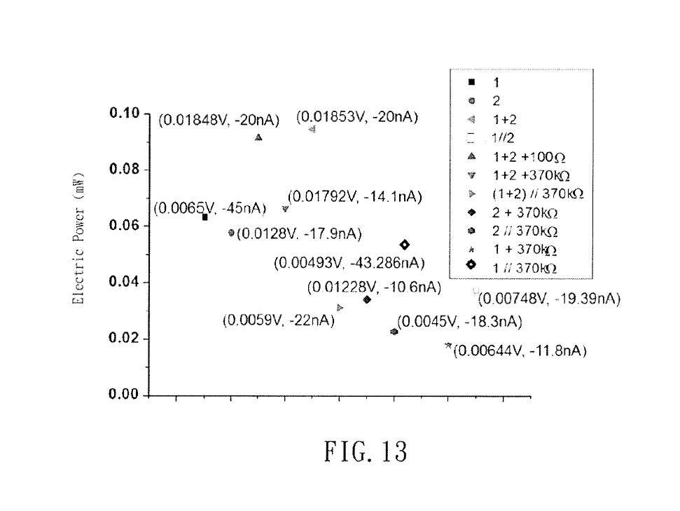

Further, as shown in FIG. 12, irradiating light of different wavelengths to the first electrode 30 and the second electrode 40 can cause generation of electric power (the electric power referred to herein is the electrical energy consumed in the circuit per unit time). Further, under the irradiation of light of the same wavelength, the embodiment with the arrangement of the lead wire 70 exhibits the best performance in electrical power generation, and the embodiment with the arrangement of the third electrode 70 exhibits the second best performance in electrical power generation. Further, as shown in FIG. 13, in actual application, two solar batteries can be connected in series (indicated in FIG. 13 by the symbol of +) or parallel (indicated in FIG. 13 by the symbol of ∥) with different sizes of resistors attached. In various connection methods, two sets of solar batteries connected in series can optimally obtain electrical power. The voltage and current values indicated in the parentheses in FIG. 13 represent the respective open-circuit voltage and short circuit current.

In conclusion, the invention provides a solar battery 10, which has a structural member 50 mounted therein for causing a surface plasmon resonance effect on the surface of the first electrode 30 and an output of electric current between the first electrode 30 and the second electrode 40. Further, mounting a third electrode 60 between the first electrode 30 and the second electrode 40 or using a lead wire 70 to connect the first electrode 30 and the second electrode 40 can enhance current output stability. When compared with conventional techniques, the invention can absorb all wavelengths of visible sunlight for photoelectric conversion, significantly improving the conversion efficiency without increasing much the manufacturing cost.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A solar battery, comprising:
a substrate having a surface;
a first electrode located on the surface of said substrate;
a second electrode located on the surface of said substrate and spaced from said first electrode at a predetermined distance so that a narrow gap is defined between said first electrode and said second electrode; and
a structural member located on one border edge of said first electrode adjacent to said narrow gap for causing creation of a surface-plasmon resonance effect on a surface of said first electrode.

2. The solar battery as claimed in claim 1, wherein said structural member is raised from the surface of said first electrode.

3. The solar battery as claimed in claim 1, further comprising a third electrode located on the surface of said substrate within said narrow gap.

4. The solar battery as claimed in claim 1, further comprising a lead wire connected to said first electrode and said second electrode and extended over said narrow gap.

5. A solar battery manufacturing method, comprising the steps of:
a) arranging a first electrode and a second electrode on a surface of a substrate in such a manner that a narrow gap is defined on the surface of said substrate between said first electrode and said second electrode; and
b) arranging a structural member on one border edge of said first electrode adjacent to said narrow gap.

6. The solar battery manufacturing method as claimed in claim 5, wherein in step b), said structural member is raised from a surface of said first electrode.

7. The solar battery manufacturing method as claimed in claim 5, further comprising a sub step of arranging a third electrode on the surface of said substrate within said narrow gap after arrangement of said first electrode and said second electrode on the surface of said substrate in step a) and before the arrangement of said structural member in step b).

8. The solar battery manufacturing method as claimed in claim 5, further comprising a sub step of extending a lead wire over said narrow gap and connecting said lead wire to said first electrode and said second electrode after the arrangement of said structural member in step b).
